(19) United States
(12) Patent Application Publication
(10) Pub. No.: US 2024/0379363 A1
(43) Pub. Date: Nov. 14, 2024

(54) METHODS FOR FORMING LOW RESISTIVITY CONTACTS

(71) Applicant: Applied Materials, Inc., Santa Clara, CA (US)

(72) Inventors: Jianqiu GUO, San Jose, CA (US); Dong WANG, San Jose, CA (US); Shumao ZHANG, San Jose, CA (US); Liqi WU, San Jose, CA (US); ShihChung CHEN, Santa Clara, CA (US); Jiang LU, Milpitas, CA (US)

(21) Appl. No.: 18/582,977

(22) Filed: Feb. 21, 2024

Related U.S. Application Data
(60) Provisional application No. 63/466,174, filed on May 12, 2023.

(51) Int. Cl. H01L 21/28

(52) U.S. Cl. CPC H01L 21/28061; H01L 21/28079

(57) ABSTRACT

Methods are provided. In some embodiments, a method of forming a contact structure on a semiconductor substrate includes disposing a selective metal silicide layer on a surface of a contact structure by maintaining a first temperature of a substrate and providing a first carrier gas, a first metal-containing precursor, and a first hydrogen-containing precursor to a first deposition chamber. The method includes disposing a partially selective metal layer on a surface of the selective metal silicide layer and one or more surfaces of a cavity by maintaining a second temperature of the substrate and providing a second carrier gas, a second metal-containing precursor, and a reducing agent to the first deposition chamber or a second deposition chamber. The second metal-containing precursor and the reducing agent are introduced to the first deposition chamber or the second deposition chamber at a chamber pressure of about 50 T to about 150 T.

### CROSS-REFERENCE TO RELATED APPLICATIONS

This application claims benefit of U.S. Patent Application Ser. No. 63/466,174, filed May 12, 2023, which is incorporated herein by reference.

### FIELD

Embodiments of the present principles generally relate to methods for forming low resistivity contacts for semiconductor device formation.

### BACKGROUND

Integrated circuits have evolved into complex devices that can include millions of transistors, capacitors, and resistors on a single chip. In the course of integrated circuit evolution, functional density (that is, the number of interconnected devices per chip area) has generally increased while geometry size (that is, the smallest component (or line) that can be created using a fabrication process) has decreased.

Microelectronic devices are fabricated on a semiconductor substrate as integrated circuits in which various conductive layers are interconnected with one another to permit electronic signals to propagate within the device. Examples of such devices include memory (for example, DRAM (dynamic random access memory)) and logic devices, including both planar and three-dimensional structures. Three-dimensional structures include finFET (fin field-effect transistor) or MOSFET (metal-oxide-semiconductor field-effect transistor) devices.

An example of finFET or MOSFET device includes a gate electrode on a gate dielectric layer on a surface of a semiconductor substrate. Source/drain regions are provided along opposite sides of the gate electrode. The source and drain regions are generally heavily doped regions of the semiconductor substrate. Usually a silicide layer, for example a titanium silicide layer, is required to form a reliable contact at the formed source and drain regions.

In a traditional middle-end-of-the-line (MEOL) contact junction formation process, a feature also referred to a cavity, a via, or a trench, is fabricated in the semiconductor substrate. MEOL contact junctions allow connections between front-end-of-the-line (FEOL) semiconductor structures and back-end-of-the-line (BEOL) interconnects. Contacts with a low resistivity are desirable in semiconductor devices. However, when MEOL contacts have high resistance, the contacts produce poor connections between the FEOL structures and the BEOL packaging interconnects, reducing the performance of the packaged semiconductor structures.

In traditional MEOL contact formation, a conformal titanium silicide (TiSi) layer is formed on a silicon or silicon germanium connection as a capping layer and then nitrided to form titanium silicon nitride (TiSiN) to prevent oxidation of the TiSi. The final silicide capping layer is a bilayer of TiSi and TiSiN that is formed over the field, sidewalls and contact regions formed on the substrate. The inventors have observed, however, that the TiSiN layer has a high resistivity (approximately 300 μohms-cm for a thickness of approximately 6 nm). The TiSi(N)/W on the field and sidewall then need to be removed by a wet pull-back process, where PVD tungsten (W) only remains at the bottom of the via. Due to PVD technology limitations, it is challenging to deposit a continuous PVD W film at the high sloped area of the capping layer. Once the pull-back process has been completed, a selective W process can either partially or fully fill up the via. For example, a feature is filled with a low resistivity metal, either by cobalt (Co) or tungsten (W). Such an integration flow not only has high resistivity due to the TiSi/TiSiN bilayer, but also high cost due to the expensive thick FFW ALD deposition process and the pull-back process for thick TiN/PVD W.

For some tungsten contact configurations, the contact structure is filled by a traditional W conformal deposition process. Conventional fill processes form a seam during the filling process, which can cause a significant (greater than 50%) line resistance increase as compared to a completely filled feature. However, a conventional silicide layer formation process involves the formation of a deposited metal containing layer to be formed on the bottom, sidewalls and field regions of the substrate that leads to the formation of a seam in the feature when a conventional conformal chemical vapor deposition (CVD) or atomic layer deposition (ALD) process is used to fill the feature.

There is a need for improved methods to reduce MEOL contact resistance and simplified processes of MEOL contact formation.

### SUMMARY

Methods for reducing middle of the line contact resistance are provided herein.

In some embodiments, a method of forming a contact structure on a semiconductor substrate includes disposing a selective metal silicide layer on a surface of a contact structure by maintaining a first temperature of a substrate and providing a first carrier gas, a first metal-containing precursor, and a first hydrogen-containing precursor to a first deposition chamber. The method includes disposing a partially selective metal layer on a surface of the selective metal silicide layer and one or more surfaces of a cavity by maintaining a second temperature of the substrate and providing a second carrier gas, a second metal-containing precursor, and a reducing agent to the first deposition chamber or a second deposition chamber. The second metal-containing precursor and the reducing agent are introduced to the first deposition chamber or the second deposition chamber at a chamber pressure of about 50 T to about 150 T. The second temperature is the same as or different than the first temperature. The second carrier gas is the same as or different than the first carrier gas. The second metal-containing precursor is the same as or different than the first metal-containing precursor.

In some embodiments, a method of forming a contact structure on a semiconductor substrate includes disposing a selective metal silicide layer having a thickness of about 3 nm to about 6 nm on a surface of a contact structure by maintaining a first temperature of a substrate and providing a first carrier gas, a first metal-containing precursor, and a first hydrogen-containing precursor to a first deposition chamber. The method includes disposing a partially selective metal layer on a surface of the selective metal silicide layer and one or more surfaces of a cavity by maintaining a second temperature of the substrate and providing a second carrier gas, a second metal-containing precursor, and a reducing agent to the first deposition chamber or a second deposition chamber. Disposing the partially selective metal layer is performed at a deposition chamber pressure of about 80 T to about 120 T. The second temperature is the same as or different than the first temperature. The second carrier gas is the same as or different than the first carrier gas. The second metal-containing precursor is the same as or different than the first metal-containing precursor.

In some embodiments, a method of forming a contact structure on a semiconductor substrate includes disposing a selective metal silicide layer having a thickness of about 3 nm to about 6 nm on a surface of a contact structure by maintaining a first temperature of a substrate and providing a first carrier gas, a first metal-containing precursor, and a first hydrogen-containing precursor to a first deposition chamber. The method includes disposing a partially selective metal layer on a surface of the selective metal silicide layer and one or more surfaces of a cavity by maintaining a second temperature of the substrate and providing a second carrier gas, a second metal-containing precursor, and a reducing agent to the first deposition chamber or a second deposition chamber. The method includes disposing a fill material on the partially selective metal layer. Disposing the partially selective metal layer is performed at a deposition chamber pressure of about 80 T to about 120 T. The second metal-containing precursor is introduced to the first deposition chamber or the second deposition chamber at a flow rate of about 0.8 slm to about 1.2 slm. The reducing agent is introduced to the first deposition chamber or the second deposition chamber at a flow rate of about 10 slm or greater. Disposing the metal layer is performed for a period of time of about 30 seconds or less. The second temperature is the same as or different than the first temperature. The second carrier gas is the same as or different than the first carrier gas. The second metal-containing precursor is the same as or different than the first metal-containing precursor. The partially selective metal layer comprises tungsten, molybdenum, or combinations thereof.

### BRIEF DESCRIPTION OF THE DRAWINGS

Embodiments of the present principles, briefly summarized above and discussed in greater detail below, can be understood by reference to the illustrative embodiments of the principles depicted in the appended drawings. However, the appended drawings illustrate only typical embodiments of the principles and are thus not to be considered limiting of scope, for the principles may admit to other equally effective embodiments.

FIG. 1A (Prior Art) is a cross-section view of a portion of a semiconductor structure, in accordance with some embodiments.

FIG. 1B is a cross-section view of a portion of a semiconductor structure, in accordance with some embodiments.

FIG. 1C is a cross-section view of a portion of a semiconductor structure, in accordance with some embodiments.

FIG. 2 is a method of reducing contact resistance, in accordance with some embodiments.

FIG. 3A is a cross-section view of a portion of a semiconductor structure, in accordance with some embodiments.

FIG. 3B is a cross-section view of a portion of a semiconductor structure, in accordance with some embodiments.

FIG. 3C is a cross-section view of a portion of a semiconductor structure, in accordance with some embodiments.

FIG. 3D is a cross-section view of a portion of a semiconductor structure, in accordance with some embodiments.

FIG. 3E is a cross-section view of a portion of a semiconductor structure, in accordance with some embodiments.

FIG. 4 depicts an integrated tool in accordance with some embodiments of the present principles, in accordance with some embodiments.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Methods of the present disclosure provide middle-end-of-the-line (MEOL) contacts with reduced resistivity. Methods can integrate multiple MEOL processes on the same integrated tool as well as achieve low contact resistance (Rc). For example, a fluorine free tungsten (FFW) process has been developed that deposits tungsten (W) onto a TiSi capping layer by use of a partially selective W growth profile such that the selectivity towards the TiSi capping layer is maintained relative to top field and sidewall dielectric surfaces. In addition to the TiSi capping layer, selectivity is also provided to a bottom surface of the structure (e.g., via) and vertical sidewall immediately proximate the TiSi capping layer, which collectively provides an improved W growth profile.

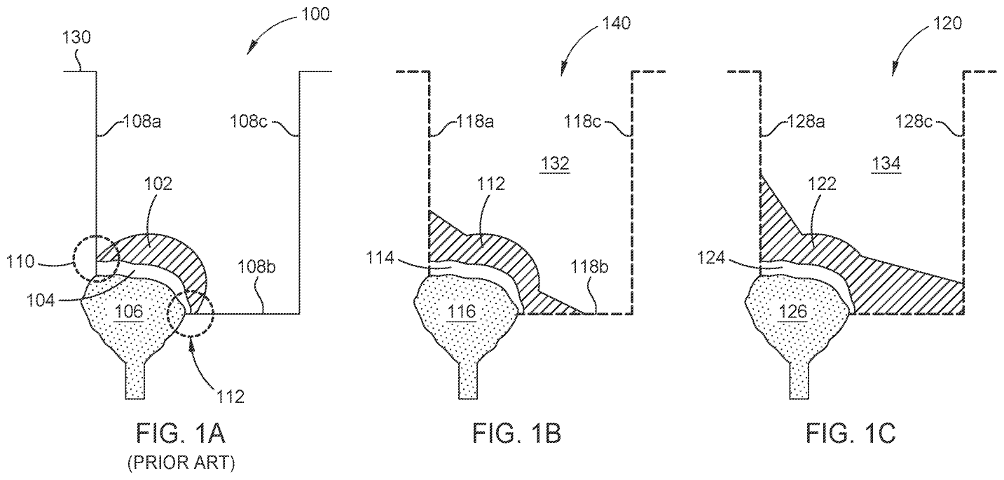

FIGS. 1A, 1B, and 1C are each a schematic illustration of a structure having a tungsten layer disposed on a TiSi capping layer. As shown in FIG. 1A (Prior Art), structure 100 has a tungsten layer 102 which has been selectively deposited on a TiSi capping layer 104. TiSi capping layer 104 is disposed on contact structure 106. For conventional selective FFW deposition processes like that shown in FIG. 1A, tungsten deposition selectivity is high on the TiSi surface instead of dielectric surfaces 108a, 108b, and 108c. However, the tungsten layer 102 is thinner at the periphery of the selective TiSi layer 104 at location 110 and location 112 where the TiSi layer 104 joins sidewall dielectric of surface 108a and bottom dielectric of surface 108b, respectively. However, at locations 110 and 112, TiSi and surrounding dielectric material at such locations is more prone to be damaged by exposure to oxygen from a subsequent vacuum break (e.g., exposure to atmosphere) or damaged due to exposure to fluorine during a subsequent W or Mo deposition process.

In contrast, fluorine free tungsten deposition processes of the present disclosure can provide a partially selective tungsten capping profile where the FFW overgrows the TiSi layer and deposits tungsten onto adjacent dielectric surfaces. For example, as shown in FIG. 1B, structure 140 has a tungsten layer 112 which has been partially selectively disposed on a TiSi capping layer 114 and over a portion of the dielectric surfaces 118a and 118b. TiSi capping layer 114 is disposed on contact structure 116. For partially selective FFW deposition like that shown in FIG. 1B, tungsten deposition selectivity is high on the TiSi surface instead of the other exposed dielectric surfaces that are not in contact with the growing FFW layer, such as the dielectric surface 118c, the upper portion of the dielectric surface 118a or field region outside of the feature. However, as shown in FIG. 1B, the tungsten deposition selectivity towards the TiSi layer 104 is reduced at the dielectric surface 118a and the dielectric surface 118b, as compared to selectivity toward TiSi layer 104 versus dielectric surface 108a and dielectric surface 108b of structure 100 of FIG. 1A.

As shown in FIG. 1C, structure 120 has a tungsten layer 122 which has been deposited on a TiSi capping layer 124. TiSi capping layer 124 is disposed on contact structure 126. For partially selective FFW deposition like that shown in FIG. 1C, tungsten deposition selectivity is high on the TiSi surface. In addition, as shown in FIG. 1C, tungsten deposition selectivity is provided at dielectric surface 128(a), dielectric surface 128(b), and dielectric surface 128(c), with at least some selectivity being preferential at dielectric surface 128(b) as compared to each of the exposed dielectric surface 128(a) and dielectric surface 128(c), and selectivity being preferential at dielectric surface 128(a) as compared to dielectric surface 128(c). Without being bound by theory, it is believed that such apparent selectivity is provided in fact by the “partial” selectivity of tungsten toward already deposited tungsten of the tungsten layer 122 as tungsten layer 122 is being formed, hence the partially selective geometry of layer formation of tungsten layer 122. By use of the processes described herein, the deposited tungsten layer is able to form over regions of the dielectric surface, and thus is not constrained to form on the TiSi layer and growing FFW layer which leads to the FFW layer and subsequent W fill layer leaving a void in the bottom of the feature if the process shown in FIG. 1A were continued on in the same selective manner. For example, the partial selectivity deposition process can form products formed by metal (e.g., tungsten) deposition onto a TiSi layer and such products also tend to deposit onto adjacent dielectric surfaces that are in proximity to the metal (e.g., tungsten) deposition also occurring. Partially selective metal deposition processes of the present disclosure can be tunable (e.g., pressure, dosing, etc.) in order to promote such partially selective metal deposition onto the TiSi surface and adjacent dielectric surfaces.

Returning to FIG. 1A (Prior Art), a conventional deposition process would also include a PVD tungsten seed layer 130 to provide tungsten seeding on bottom SiO₂ or SiN (e.g., Si₃N₄) surfaces of dielectric surface 108b, which is then followed by a subsequent selective dry pull-back process selectively removes (not shown) portions of the PVD tungsten seed layer from dielectric surface 108a and dielectric surface 108c. However, as shown FIGS. 1B and 1C, partially selective FFW deposition processes of the present disclosure render such PVD tungsten seed layer (and processes thereof) and subsequent selective dry pull back processes to be merely optional, e.g., not present and not performed, because partially selective FFW deposition processes can provide sufficient tungsten deposition at surface 118b (FIG. 1B) and/or surface 118b (FIG. 1C) to provide a sufficient tungsten seeding for subsequent metal gap fill deposition of the remainder of the cavity 132 (FIG. 1B) and/or cavity 134 (FIG. 1C), e.g., as described in more detail below. Having a capability to eliminate PVD tungsten seed layer deposition significantly simplifies the challenges of bottom-up fill process flows while also achieving low contact resistance (Rc) contact structures.

### Processes

Processes of the present disclosure can provide titanium silicide (TiSi) capping layers that can be capped with partially selective tungsten (W) to eliminate the need for a plasma vapor deposition (PVD) tungsten seed layer from the contact film stack, achieving low contact Rc. In addition, selective pull back of one or more portions of the partially selective tungsten layer is optional before subsequent bottom-up tungsten fill of the structure. For example, tungsten deposition is used to provide bottom-up tungsten fill in some embodiments to further reduce the Rc of the structure. The methods of the present disclosure also leverage a highly selective chemical vapor deposition (CVD) TiSi deposition process along with an in-situ TiSi/W integration flow.

In brief, processes provide several key integration benefits for MEOL contact structures. Highly selective CVD TiSi deposition on Si eliminates TiSiN capping layers which reduces contact Rc, partially selective FFW+PVD W metal capping that provides an oxidation and fluorine barrier that further reduces the resistance Rc, simple and low-cost dry process for TiSi/W pull back (etch) which is optional, integrated bottom-up fill W flow which reduces overall Rc and cost, integrated W fill, and W can be replaced by Mo capping layer and/or gapfill.

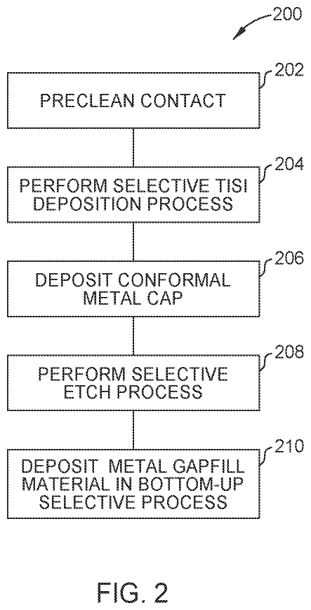

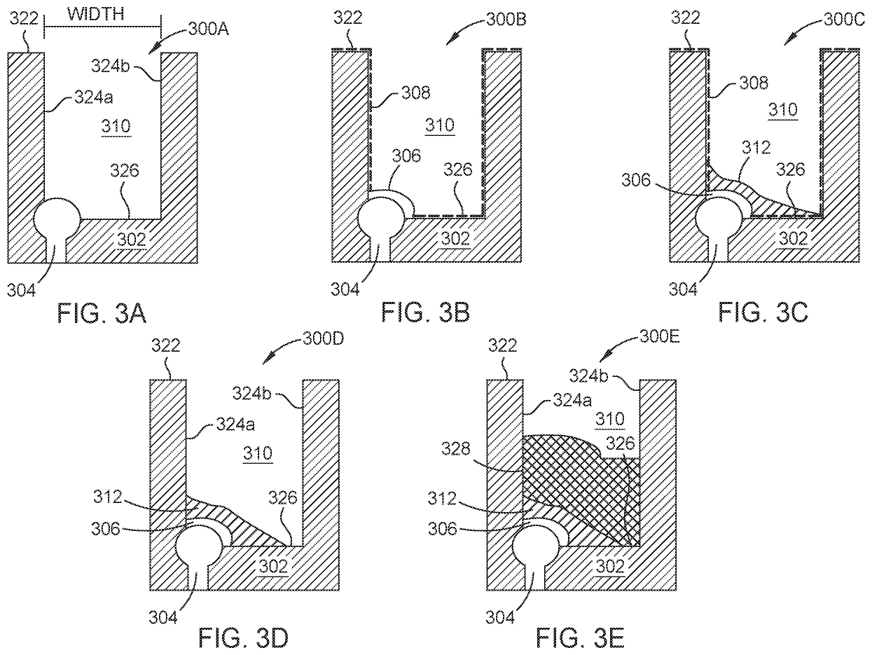

The methods of the present disclosure can be effective for metal gapfill processes in general and may be used with other metal gapfill material besides tungsten such as, for example, molybdenum and the like. For the sake of brevity, examples discussed use tungsten but are not meant to be limited to only tungsten. In the method 200 of FIG. 2, a highly selective CVD TiSi deposition and in-situ TiSi/W integration flow while eliminating a PVD W seed layer reduces the high-cost fluorine free metal deposition processes overall. In the discussion of the method 200, references will be made to the views 300A-300E of FIGS. 3A-3E. In block 202, a preclean process is performed to remove any contaminates and/or oxidation from surfaces of a contact structure as depicted in a view 300A of FIGS. 3A-3E. The contact structure has a silicon-based portion 304 that is exposed in a cavity 310 of a substrate 302 formed of a dielectric material (e.g., silicon dioxide, silicon nitride, etc.). In some embodiments, the silicon-based portion 304 may be a silicon material or a silicon germanium (SiGe) material.

In one or more embodiments, cavities (e.g., vias) can have an average width. For example, cavity 310 can have a width (shown in FIG. 3A) of about 35 nanometers (nm) or less, such as about 5 nm to about 35 nm, such as about 5 nm, 10 nm, and 15 nm to about 20 nm, 25 nm, 30 nm, or 35 nm. In one or more embodiments, cavity 310 can have an aspect ratio (depth:width) of about 1:1 to about 100:1, such as about 10:1, 15:1, or 25:1 to about 35:1, 45:1, or 50:1.

In block 204, a selective TiSi deposition process is performed to produce a TiSi layer 306 on the silicon-based portion 304 as depicted in a view 300B of FIG. 3B. TiSi is TiₓSi_{y} which may include Ti₅Si₃, TiSi₂, TiSi, or combinations thereof. In alternative embodiments, layer 306 is either of titanium or silicon. The process is selective to the silicon-based portion 304 over the dielectric material of the substrate 302, but a thin TiSi layer 308 may also form on the surfaces of the field 322 of the substrate 302 and on sidewalls 324a, 324b in the cavity 310, including a bottom surface 326 of the cavity 310. In some embodiments, the selective TiSi deposition process is a CVD TiSi process with selectivity on silicon (Si) or silicon germanium (SiGe) over oxide/SiN of approximately greater than 30:1 (vol/vol). With a deposition thickness of TiSi of approximately 3 nm to approximately 6 nm on the silicon-based portion 304, a selectivity loss on the field 322 or sidewalls 324a, 324b and the bottom surface 326 of the cavity 310 is generally less than approximately 1 angstrom to approximately 3 angstroms. Thus, the CVD TiSi process provides a good basis for in-situ selective FFW growth.

Selective TiSi deposition can be performed using any suitable CVD or ALD process. In some embodiments, the CVD or ALD process includes utilizing a plasma with a carrier gas. The plasma/carrier gas may then be introduced towards the surface of the semiconductor substrate. In one or more embodiments, the carrier gas includes a noble gas, such as argon, neon, helium, or combinations thereof.

In one or more embodiments, selective TiSi deposition is performed by introducing a hydrogen-containing precursor by utilizing a conductively coupled plasma (CCP) deposition. In one or more embodiments, selective TiSi deposition includes introducing a hydrogen-containing precursor and a metal-containing precursor with the carrier gas. In one or more embodiments, the metal-containing precursor gas may be fluorine free to prevent formation of metal fluoride solids that have undesirable resistivity properties. The hydrogen-containing precursor can include molecular hydrogen (H₂) and the metal-containing precursor is titanium chloride (TiCl₄). Without being bound by theory, the introduction of both the hydrogen-containing and the metal-containing precursors into the carrier gas causes both precursors to become energized on a molecular level to a point of at least partial disassociation in the carrier gas. For example, titanium chloride may disassociate into titanium-based ions (Ti⁺, TiClₓ⁺) or free radial titanium trichloride (TiCl₃*); hydrogen may disassociate into hydronium ions (H⁺) or hydrogen free radicals (H*). The dissociated species may then interact with the silicon surface of the silicon-containing contact, donate electrons to the silicon atoms and then each species interact with one another and form the titanium silicide layer on the top of the silicon-containing contact 306.

In one or more embodiments, the selective TiSi deposition is performed by maintaining the semiconductor substrate at a first metal deposition temperature. In one or more embodiments, the semiconductor substrate is maintained at a metal deposition temperature of about 200° C. to 800° C., such as about 200° C., 300° C., 400° C., 450° C., and 500° C. to about 600° C., 700° C., and 800° C. In one or more embodiments, selective TiSi deposition is maintained for a period of about 5 seconds to about 20 seconds, such as about 10 second to about 15 seconds. In one or more embodiments, selective TiSi deposition may further include introducing an inert gas to the semiconductor substrate to evacuate the products from the metal deposition. The introduced inert gas may have an elevated temperature, such as about 100° C. to about 150° C., such as from about 100° C., 110° C., 120° C., and 125° C. to about 130° C., 140° C. and 150° C. The inert gas flowing over the semiconductor substrate may facilitate in cooling and affixing the deposition material (e.g., TiSi) on the top of the silicon-containing contact as well as removing volatilized products and unreacted materials, such as molecular hydrogen and hydrogen chloride (HCl).

In block 206, a partially selective metal cap 312 is deposited on the TiSi layer 306 on the silicon-based portion 304 as depicted in a view 3000 of FIG. 3C. In some embodiments, a partially selective metal cap has an average thickness of about 5 nm to about 11 nm, such as about 6 nm to about 9 nm, such as about 8 nm. Partially selective metal cap 312 can be deposited by any suitable deposition process, such as CVD or ALD. The partially selective metal cap 312 may be deposited using a partially selective deposition process that is a fluorine free metal deposition process of the metal material used for forming the selective metal cap 312. In some embodiments, the partially selective metal cap 312 may be formed of tungsten. In some embodiments, the partially selective metal cap 312 may be formed of molybdenum. For example, in some embodiments, an in-situ partially selective FFW material is deposited on the TiSi layer as a silicide capping layer. In so doing, a highly resistive TiSiN layer is eliminated from the process flow because the in-situ deposition process eliminates the TiSi layer from being exposed to oxygen prior to the deposition of the partially selective metal cap 312. In some embodiments, the partially selective FFW process can be from a halide based atomic layer deposition (ALD) process. In some embodiments, the partially selective FFW process can be from a metal chloride process such as from a CVD (WCl₅+H₂) process or from a CVD (WCl₆+H₂) process. In some embodiments, the partially selective FFW process can be from a process using metalorganic precursors.

Partially selective metal cap 312 can include cobalt (Co), molybdenum (Mo), tungsten (W), tantalum (Ta), titanium (Ti), ruthenium (Ru), rhodium (Rh), copper (Cu), iron (Fe), manganese (Mn), vanadium (V), niobium (Nb), hafnium (Hf), zirconium (Zr), yttrium (Y), aluminum (Al), tin (Sn), chromium (Cr), lanthanum (La), iridium (Ir), or combinations thereof. In some embodiments, the partially selective metal cap 312 may be formed of tungsten. In some embodiments, the partially selective metal cap 312 may be formed of molybdenum. In some embodiments, for example, a partially selective metal cap provides metal seeding on a bottom of the cavity 310 (e.g., SiO₂ or SiN surface where partially selective FFW has grown).

As part of a process of depositing partially selective metal cap 312 onto the selective TiSi layer 306 during process 206, both a metal-containing precursor and a reducing agent are introduced in the process chamber with a carrier gas to form a gas mixture. The gas mixture is then introduced towards the surface of the semiconductor substrate 302. The carrier gas may include a noble gas, such as argon, neon, and helium, and combinations thereof.

As part of a process of depositing partially selective metal cap 312 onto the selective TiSi layer 306, the semiconductor substrate 302 may be maintained at a metal deposition temperature. In one or more embodiments, the substrate 302 is maintained at a metal deposition temperature of about 400° C. to 550° C., such as from about 400° C., 425° C., 450° C., 475° C., to about 475° C., about 500° C., about 525° C. or 550° C., such as about 450° C. to about 470° C. In one or more embodiments, a chamber pressure at which the partially selective metal deposition process is performed is about 50 T to about 150 T, such as about 80 T to about 120 T, such as about 80 T to about 100 T, alternatively about 100 T to about 120 T. In one or more embodiments, the period of time at which the partially selective metal deposition process is performed is about 5 seconds to about 45 seconds, such as about 30 seconds or less, such as about 10 seconds to about 25 seconds. In one or more embodiments, both the selective TiSi deposition process and the partially selective metal deposition process occur in the same process chamber or in different process chambers.

The partially selective metal cap 312 may utilize a metal-containing precursor, such as a fluorine free second metal-containing precursor. In one or more embodiments, the introduced metal-containing precursor includes a fluorine-free metal halide. For example, the metal-containing precursor may include a fluorine-free tungsten precursor (FFW). Examples of FFW halides can include tungsten pentachloride (WCl₅), tungsten hexachloride (WCl₆), or combinations thereof. In one or more embodiments, the fluorine-free tungsten precursor includes a tungsten oxyhalide precursor. Examples of a tungsten oxyhalide can include tungsten oxytetrachloride (WOCl₄), tungsten dichloride dioxide (WO₂Cl₂), or combinations thereof. In one or more embodiments, the fluorine-free tungsten precursor is also a chlorine-free tungsten precursor (CFW). Examples of a fluorine-free and chloride-free tungsten precursor can include tungsten pentabromide (WBr₅), tungsten hexabromide (WBr₆), or combinations thereof. In one or more embodiments, the metal-containing precursor includes a fluorine-free metal organic, such as tris(3-hexyne) tungsten carbonyl (W(CO)(CH₃CH₂C≡CCH₂CH₃)₃).

As part of the process of depositing a partially selective metal cap 312 onto the TiSi layer 306 during the process 206, a reducing agent that is reactive with a metal-containing precursor is introduced into the carrier gas along with the metal-containing precursor. The reducing agent may be a hydrogen-containing composition, such as molecular hydrogen (H₂), ammonia (NH₃), hydrazine (N₂H₄), silane (SiH₄), disilane (Si₂H₆), trisilane (Si₃H₈), and tetrasilane (Si₄H₁₀), or combinations thereof. The reducing agent acts as a proton donor to cause the metal-containing precursor to form a metallic film comprising the metal on top of the TiSi layer.

The deposition process 206 may include maintaining a flow rate of the metal-containing precursor to a flow rate of the reducing agent into the carrier gas until a partially selective metal cap 312 forms on the TiSi layer 306. In one or more embodiments, reducing agent (e.g., H₂) is provided to the chamber at a flow rate of about 10 slm or greater, such as about 10 slm to about 100 slm, such as about 15 slm to about 50 slm. In one or more embodiments, the metal-containing precursor is provided to the chamber at an ampoule temperature of about 100° C. or greater and a flow rate of about 0.5 slm to about 2 slm, such as about 0.8 slm to about 1.2 slm. In one or more embodiments, the metal-containing precursor and the reducing agent are introduced (into the carrier gas) at a molar ratio of about 10:1 to 1:100, such as about 10:1, 5:1, 2:1, and 1:1 to about 1:2, 1:5, 1:10, 1:20, 1:50, and 1:100. In one or more embodiments, the combined flow rates of metal-containing precursor and reducing agent are in a range of from about 1 vol. % to 70 vol. % of the overall gas mixture, where the remainder of the gas mixture includes the carrier gas.

At high-pressure, high flow conditions, the deposition rate of partially selective metal cap is high. Such conditions can cause selectivity loss at the sidewalls 324a, 324b, and 326. Without being bound by theory, the mechanism of selectivity loss is believed to provide higher concentration of reaction byproduct formed at the TiSi interface. Under high pressure where diffusion is limited, such byproduct will not be easily removed from the cavity 310 but will adsorb to sidewalls of the cavity in a bottom to top direction. These adsorbed metal byproducts will act as nucleation centers for FFW growth. For example, if deposition time is long enough, selectivity will occur from bottom to top trench creating a V-shape profile of the partially selective metal cap 312.

By comparison, for prior “selective” FFW deposition, the process conditions are more in the lower pressure regime <35 T. WCl₅ dosage is much lower (amp temp <100 C, carrier flow <0.6 slm) and process temp is at 450˜470 C range. For this process condition, the interaction between WCl₅ and TiSi is milder and the byproduct that leads to selectivity loss is in lower concentration. Plus the pressure is much lower too which promotes diffusion, and the byproduct will have a better chance to be removed from the cavity before causing selectivity loss. In this case, at regions where the tungsten cap merges with dielectric sidewall, the resulting better selectivity will lead to thinner tungsten thickness compared to cavity center.

In one or more embodiments, the process of depositing a partially selective metal cap 312 onto the TiSi layer 306, such as process 206, includes introducing an inert gas to the partially selective metal cap deposited semiconductor substrate. The inert gas evacuates the carrier gas, reactants, and products from the partially selective metal cap deposited semiconductor substrate and process chamber used to form the partially selective metal cap deposited semiconductor.

After deposition of the partially selective metal cap 312, a process may be used to perform a bottom-up gapfill (blocks 208, 210 of FIG. 2). For a bottom-up gapfill process, in block 210, a selective etch process (block 208) is optionally performed and is depicted in a view 300D of FIG. 3D. For example, a simple and low cost in-situ dry etch or wet etch process can remove approximately 3 nm to approximately 4 nm of the partially selective metal cap 312 on the field 322 and/or sidewalls 324a, 324b of the cavity 310, leaving the bottom surface 326 with a portion of the partially selective metal cap 312 disposed thereon (see view 300D of FIG. 3D). The tungsten pull-back does not have to be performed in-situ (in the same integrated tool as the above processes) and is merely optional.

In block 210, a metal gapfill material 328 is deposited in a bottom-up selective process (e.g., a tungsten hexafluoride (WF₆) based selective process (tungsten over dielectric material of the sidewalls 324a, 324b of the cavity 310, etc.)) as depicted in a view 300E of FIG. 3E. After an optional wet/dry pull-back (etch) of block 208, partially selective metal cap 312 remains at the bottom of the structure and on the silicon-based portion as shown in FIG. 3D, which provides a seed layer, for example, for a selective CVD W bottom-up gapfill.

In some embodiments, a conformal gapfill may be used instead of a bottom-up fill. In some embodiments, for example, the cavity 310 may be filled by conformal CVD using tungsten or molybdenum and the like. In some embodiments, a conformal molybdenum fill can be performed by using MoO₂Cl₂ or MoOCl₄+H₂ processes or a mixture of MoCl₅ with the aforementioned two precursors.

As stated previously, in addition to tungsten as a TiSi capping layer, molybdenum (Mo) can be used as a capping material as well by selective Mo process. Similarly, the structure fill can be done by selective Mo fill or conformal Mo fill. In some embodiments, Mo and W materials can be interchanged or mixture of Mo and W used.

In FIG. 3E, a resultant conformal metal gap fill material 328 has been conformally deposited into cavity 310. In FIG. 3E, metal gap fill material 328 is shown filling the device cavity 310. The metal gap fill material 328 is shown in contact with the partially selective metal cap 312 such that the metal gap fill material 328 is in electrical communication with the contact structure 304. The metal gap fill material 328 is also in contact with at least a portion of the sidewalls 324a, 324b.

Any suitable chemical deposition process, including but not limited to CVD or ALD processes, may be utilized for the metal gap fill material process 210. The metal gap fill material may be applied such that the material is deposited onto the bottom portion of the device feature and then grown upwards towards the semiconductor field region such that the resultant gap fill material at least approaches the field region (as shown in FIG. 3E) or is at least partially level with the field region (not shown).

In one or more embodiments, the metal gap fill material includes one or more of cobalt (Co), molybdenum (Mo), tungsten (W), tantalum (Ta), titanium (Ti), ruthenium (Ru), rhodium (Rh), copper (Cu), iron (Fe), manganese (Mn), vanadium (V), niobium (Nb), hafnium (Hf), zirconium (Zr), yttrium (Y), aluminum (Al), tin (Sn), chromium (Cr), lanthanum (La), iridium (Ir), or any combination thereof. In one or more embodiments, the metal gap fill material includes tungsten (e.g., deposited using WF₆). In one or more embodiments, the conductor material includes molybdenum.

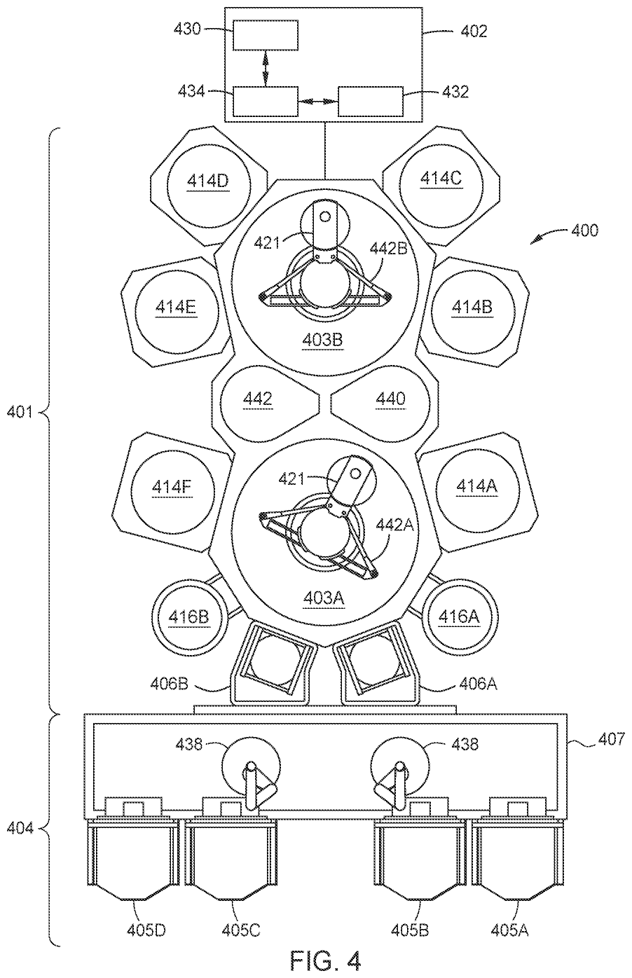

The methods of the present disclosure may be performed in individual process chambers that may be provided as part of a cluster tool, for example, the integrated tool 400 (e.g., cluster tool) described below with respect to FIG. 4. The advantage of using an integrated tool 400 is that there is no vacuum break between chambers and, therefore, no requirement to degas and pre-clean a substrate before treatment in a chamber. For example, in some embodiments the methods of the present disclosure may advantageously be performed in an integrated tool such that there are limited or no vacuum breaks between processes, limiting or preventing contamination of the substrate such as oxidation and the like. The integrated tool 400 includes a vacuum-tight processing platform 401, a factory interface 404, and a system controller 402. The processing platform 401 comprises multiple processing chambers, such as 414A, 413B, 414C, 414D, 414E, and 414F operatively coupled to a vacuum substrate transfer chamber (transfer chambers 403A, 403B). The factory interface 404 is operatively coupled to the transfer chamber 403A by one or more load lock chambers (two load lock chambers, such as 406A and 406B shown in FIG. 4).

In some embodiments, the factory interface 404 comprises at least one docking station 407, at least one factory interface robot 438 to facilitate the transfer of the semiconductor substrates. The docking station 407 is configured to accept one or more front opening unified pod (FOUP). Four FOUPS, such as 405A, 405B, 405C, and 405D are shown in the embodiment of FIG. 4. The factory interface robot 438 is configured to transfer the substrates from the factory interface 404 to the processing platform 401 through the load lock chambers, such as 406A and 406B. Each of the load lock chambers 406A and 406B have a first port coupled to the factory interface 404 and a second port coupled to the transfer chamber 403A. The load lock chamber 406A and 406B are coupled to a pressure control system (not shown) which pumps down and vents the load lock chambers 406A and 406B to facilitate passing the substrates between the vacuum environment of the transfer chamber 403A and the substantially ambient (e.g., atmospheric) environment of the factory interface 404. The transfer chambers 403A, 403B have vacuum robots 442A, 442B disposed in the respective transfer chambers 403A, 403B. The vacuum robot 442A is capable of transferring substrates 421 between the load lock chamber 406A, 406B, the processing chambers 414A and 414F and a cooldown station 440 or a pre-clean station 442. The vacuum robot 442B is capable of transferring substrates 421 between the cooldown station 440 or pre-clean station 442 and the processing chambers 414B, 414C, 414D, and 414E.

In some embodiments, the processing chambers 414A, 414B, 414C, 414D, 414E, and 414F are coupled to the transfer chambers 403A, 403B. The processing chambers 414A, 414B, 414C, 414D, 414E, and 414F may comprise, for example, preclean chambers, ALD process chambers, PVD process chambers, remote plasma chambers, CVD chambers, or the like. The chambers may include any chambers suitable to perform all or portions of the methods of the present disclosure, as discussed above, such as PVD W or PVD Mo chambers, CVD chambers, ALD chambers and the like. In some embodiments, one or more optional service chambers (shown as 416A and 416B) may be coupled to the transfer chamber 403A. The service chambers 416A and 416B may be configured to perform other substrate processes, such as degassing, orientation, substrate metrology, cool down, and the like.

The processing chambers 420, 422, 424, 426, 428, 430 may be any appropriate chamber for processing a substrate. In some examples, a processing chamber may be capable of performing an etch process, a cleaning process, an annealing process, a CVD deposition process, or an ALD deposition processes. As used herein, CVD refers to chemical vapor deposition and ALD refers to atomic line deposition. In some embodiments, a processing chamber is a Selectra™ Etch chamber available from Applied Materials of Santa Clara, Calif. In some embodiments, a processing chamber is a SiCoNi™ Pre-clean chamber available from Applied Materials of Santa Clara, Calif. In some embodiments, a processing chamber may be a Centura™ Epi chamber, Volta™ CVD/ALD chamber, or Encore™ PVD chamber, all available from Applied Materials of Santa Clara, Calif.

The system controller 402 controls the operation of the tool 400 using a direct control of the process chambers 414A, 414B, 414C, 414D, 414E, and 414F or alternatively, by controlling the computers (or controllers) associated with the process chambers 414A, 414B, 414C, 414D, 414E, and 414F and the tool 400. In operation, the system controller 402 enables data collection and feedback from the respective chambers and systems to optimize performance of the tool 400. The system controller 402 generally includes a Central Processing Unit (CPU) 430, a memory 434, and a support circuit 432. The CPU 430 may be any form of a general-purpose computer processor that can be used in an industrial setting. The support circuit 432 is conventionally coupled to the CPU 430 and may comprise a cache, clock circuits, input/output subsystems, power supplies, and the like. Software routines, such as a method as described above may be stored in the memory 434 and, when executed by the CPU 430, transform the CPU 430 into a specific purpose computer (system controller) 402. The software routines may also be stored and/or executed by a second controller (not shown) that is located remotely from the tool 400.

Embodiments in accordance with the present principles may be implemented in hardware, firmware, software, or any combination thereof. Embodiments may also be implemented as instructions stored using one or more computer readable media, which may be read and executed by one or more processors. A computer readable medium may include any mechanism for storing or transmitting information in a form readable by a machine (e.g., a computing platform or a “virtual machine” running on one or more computing platforms). For example, a computer readable medium may include any suitable form of volatile or non-volatile memory. In some embodiments, the computer readable media may include a non-transitory computer readable medium.

Certain embodiments and features have been described using a set of numerical upper limits and a set of numerical lower limits. It should be appreciated that ranges including the combination of any two values, e.g., the combination of any lower value with any upper value, the combination of any two lower values, and/or the combination of any two upper values are contemplated unless otherwise indicated. Certain lower limits, upper limits and ranges appear in one or more claims below. All numerical values are “about” or “approximately” the indicated value, and take into account experimental error and variations that would be expected by a person having ordinary skill in the art.

Likewise whenever a composition, an element or a group of elements is preceded with the transitional phrase “comprising”, it is understood that we also contemplate the same composition or group of elements may be modified with other transitional phrases, such as “consisting essentially of,” “consisting of”, “selected from the group of consisting of,” or “is” preceding the recitation of the composition, element, or elements and vice versa. The phrases, unless otherwise specified, “consists essentially of” and “consisting essentially of” do not exclude the presence of other steps, elements, or materials, whether or not, specifically mentioned in this specification, so long as such steps, elements, or materials, do not affect the basic and novel characteristics of the claimed features, additionally, the phrases do not exclude impurities and variances normally associated with the elements and materials used.

While the foregoing is directed to embodiments of the present principles, other and further embodiments of the principles may be devised without departing from the basic scope thereof.

1. A method of forming a contact structure on a semiconductor substrate, comprising:
disposing a selective metal silicide layer on a surface of a contact structure by maintaining a first temperature of a substrate and providing a first carrier gas, a first metal-containing precursor, and a first hydrogen-containing precursor to a first deposition chamber; and
forming a metal layer on a surface of the selective metal silicide layer and a portion of a dielectric surface of a feature of the contact structure by maintaining a second temperature of the substrate and providing a second carrier gas, a second metal-containing precursor, and a reducing agent to the first deposition chamber or a second deposition chamber, wherein the second metal-containing precursor and the reducing agent are introduced to the first deposition chamber or the second deposition chamber at a chamber pressure of about 50 T to about 150 T, the second temperature is the same as or different than the first temperature, the second carrier gas is the same as or different than the first carrier gas, and the second metal-containing precursor is the same as or different than the first metal-containing precursor.

2. The method of claim 1, wherein:
the first hydrogen-containing precursor is H₂,
the first metal-containing precursor is TiCl₄, and
the first temperature of the substrate is about 200° C. to 800° C.

3. The method of claim 1, wherein:
the reducing agent is selected from the group consisting of H₂, ammonia, hydrazine, silane, disilane, trisilane, tetrasilane, and combinations thereof,
the second metal-containing precursor is WCl₅ or WCl₆, and
the second temperature of the substrate is about 450° C. to 470° C.

4. The method of claim 1, wherein the metal layer comprises tungsten, molybdenum, or combinations thereof.

5. The method of claim 1, wherein:
the metal layer is disposed at least partially contacting a first dielectric surface adjacent the surface of the selective metal silicide layer, and
the metal layer is disposed at least partially contacting a second dielectric surface adjacent the surface of the selective metal silicide layer, wherein the second dielectric surface is substantially orthogonal to the first dielectric surface.

6. The method of claim 1, wherein disposing the metal layer is performed at a deposition chamber pressure of about 80 T to about 120 T.

7. The method of claim 6, wherein disposing the metal layer is performed for a period of time of about 30 seconds or less.

8. The method of claim 1, wherein the second metal-containing precursor is introduced to the first deposition chamber or the second deposition chamber at a flow rate of about 0.8 slm to about 1.2 slm.

9. The method of claim 8, wherein the reducing agent is introduced to the first deposition chamber or the second deposition chamber at a flow rate of about 10 slm or greater.

10. The method of claim 1, wherein:
the first hydrogen-containing precursor is H₂,
the first metal-containing precursor is TiCl₄,
the first temperature of the substrate is about 200° C. to 800° C.,
the reducing agent is selected from the group consisting of H₂, ammonia, hydrazine, silane, disilane, trisilane, tetrasilane, and combinations thereof,
the second metal-containing precursor is WCl₅ or WCl₆, and
the second temperature of the substrate is about 450° C. to 470° C.

11. The method of claim 1, further comprising disposing a fill material on the metal layer.

12. A method of forming a contact structure on a semiconductor substrate, comprising:
disposing a selective metal silicide layer having a thickness of about 3 nm to about 6 nm on a surface of a contact structure by maintaining a first temperature of a substrate and providing a first carrier gas, a first metal-containing precursor, and a first hydrogen-containing precursor to a first deposition chamber; and
disposing a metal layer on a surface of the selective metal silicide layer and one or more surfaces of a cavity by maintaining a second temperature of the substrate and providing a second carrier gas, a second metal-containing precursor, and a reducing agent to the first deposition chamber or a second deposition chamber, wherein disposing the metal layer is performed at a deposition chamber pressure of about 80 T to about 120 T, the second temperature is the same as or different than the first temperature, the second carrier gas is the same as or different than the first carrier gas, and the second metal-containing precursor is the same as or different than the first metal-containing precursor.

13. The method of claim 12, wherein:
the first hydrogen-containing precursor is H₂,
the first metal-containing precursor is TiCl₄, and
the first temperature of the substrate is about 200° C. to 800° C.

14. The method of claim 12, wherein:
the reducing agent is selected from the group consisting of H₂, ammonia, hydrazine, silane, disilane, trisilane, tetrasilane, and combinations thereof,
the second metal-containing precursor is WCl₅ or WCl₆, and
the second temperature of the substrate is about 450° C. to 470° C.

15. The method of claim 12, wherein the metal layer comprises tungsten, molybdenum, or combinations thereof.

16. The method of claim 12, wherein:
the metal layer is disposed at least partially contacting a first dielectric surface adjacent the surface of the selective metal silicide layer, and
the metal layer is disposed at least partially contacting a second dielectric surface adjacent the surface of the selective metal silicide layer, wherein the second dielectric surface is substantially orthogonal to the first dielectric surface.

17. The method of claim 16, wherein:
the second metal-containing precursor is introduced to the first deposition chamber or the second deposition chamber at a flow rate of about 0.8 slm to about 1.2 slm, and
the reducing agent is introduced to the first deposition chamber or the second deposition chamber at a flow rate of about 10 slm or greater.

18. The method of claim 12, wherein disposing the metal layer is performed for a period of time of about 30 seconds or less.

19. The method of claim 12, further comprising disposing a fill material on the metal layer.

20. A method of forming a contact structure on a semiconductor substrate, comprising:
disposing a selective metal silicide layer having a thickness of about 3 nm to about 6 nm on a surface of a contact structure by maintaining a first temperature of a substrate and providing a first carrier gas, a first metal-containing precursor, and a first hydrogen-containing precursor to a first deposition chamber;
disposing a metal layer on a surface of the selective metal silicide layer and one or more surfaces of a cavity by maintaining a second temperature of the substrate and providing a second carrier gas, a second metal-containing precursor, and a reducing agent to the first deposition chamber or a second deposition chamber; and
disposing a fill material on the metal layer,
wherein:
disposing the metal layer is performed at a deposition chamber pressure of about 80 T to about 120 T,
the second metal-containing precursor is introduced to the first deposition chamber or the second deposition chamber at a flow rate of about 0.8 slm to about 1.2 slm,
the reducing agent is introduced to the first deposition chamber or the second deposition chamber at a flow rate of about 10 slm or greater,
disposing the metal layer is performed for a period of time of about 30 seconds or less,
the second temperature is the same as or different than the first temperature,
the second carrier gas is the same as or different than the first carrier gas,
the second metal-containing precursor is the same as or different than the first metal-containing precursor, and
the metal layer comprises tungsten, molybdenum, or combinations thereof.
